(19) United States
(12) Patent Application Publication
(10) Pub. No.: US 2026/0190219 A1
(43) Pub. Date: Jul. 2, 2026

(54) DISPLAY APPARATUS AND CENTRAL CONTROL PLATFORM

(71) Applicant: AUO Corporation, Hsinchu City (TW)

(72) Inventors: Chih-Hung Wu, Hsinchu City (TW); Sheng-Hsun Chou, Hsinchu City (TW); Shu-Te Ho, Hsinchu City (TW); Wei-Lun Hung, Hsinchu City (TW)

(73) Assignee: AUO Corporation, Hsinchu City (TW)

(21) Appl. No.: 19/253,951

(22) Filed: Jun. 29, 2025

(30) Foreign Application Priority Data
Dec. 30, 2024 (TW) 113151478

(51) Int. Cl. H05K 1/02; H05K 1/03

(52) U.S. Cl. CPC H05K 1/0283; H05K 1/036; H05K 2201/0195

(57) ABSTRACT

A display apparatus including a first panel, a first stretchable film and a first adhesive layer is provided. The first stretchable film is disposed on one side of the first panel. The first adhesive layer connects the first panel and the first stretchable film. A ratio of the Young's modulus of the first panel to the Young's modulus of the first adhesive layer is greater than or equal to 1000. A central control platform is also provided.

### CROSS-REFERENCE TO RELATED APPLICATION

This application claims the priority benefit of Taiwan application serial no. 113151478, filed on Dec. 30, 2024. The entirety of the above-mentioned patent application is hereby incorporated by reference herein and made a part of this specification.

### BACKGROUND

### Technical Field

The disclosure relates to a display apparatus and a central control platform, and more particularly to a stretchable display apparatus and a central control platform.

### Description of Related Art

A conventional display apparatus combines a stretchable panel with a deformation mechanism, and its operating surface is capable of deformation. The stretchable panel, for example, is a stacked structure composed of at least one panel, at least one adhesive layer, and at least one stretchable film. However, the material combination used in current structures limits the deformation capability of the stretchable panel.

### SUMMARY

The disclosure provides a display apparatus and a central control platform with a larger and more stable deformation capacity.

A display apparatus of the disclosure includes a first panel, a first stretchable film and a first adhesive layer. The first stretchable film is disposed on one side of the first panel. The first adhesive layer connects the first panel and the first stretchable film. A ratio of the Young's modulus of the first panel to the Young's modulus of the first adhesive layer is greater than or equal to 1000.

In an embodiment of the disclosure, the display apparatus further includes a second adhesive layer which is disposed on one side of the first panel facing away from the first stretchable film and connects the first panel. A ratio of the Young's modulus of the first panel to the Young's modulus of the second adhesive layer is greater than or equal to 1000.

In an embodiment of the disclosure, a thickness of each of the first adhesive layer and the second adhesive layer of the display apparatus is greater than a thickness of the first panel.

In an embodiment of the disclosure, the display apparatus further includes a second stretchable film which is disposed on one side of the second adhesive layer facing away from the first panel and connects the second adhesive layer. The Young's modulus of each of the first stretchable film and the second stretchable film is less than the Young's modulus of the first panel.

In an embodiment of the disclosure, the display apparatus further includes a second panel and a third adhesive layer. The second panel is disposed on one side of the second stretchable film facing away from the first panel. The third adhesive layer connects the second panel and the second stretchable film. A ratio of the Young's modulus of the second panel to the Young's modulus of the third adhesive layer is greater than or equal to 1000.

In an embodiment of the disclosure, the Young's modulus of each of the first pane and the second panel is less than 100 MPa.

In an embodiment of the disclosure, the display apparatus further includes a fourth adhesive layer and a third stretchable film. The fourth adhesive layer is disposed on one side of the second panel facing away from the first panel and connects the second panel. A ratio of the Young's modulus of the second panel to the Young's modulus of the fourth adhesive layer is greater than or equal to 1000. The third stretchable film is disposed on one side of the fourth adhesive layer facing away from the second panel and connects the fourth adhesive layer. The Young's modulus of the third stretchable film is less than the Young's modulus of the second panel.

In an embodiment of the disclosure, a thickness of each of the third adhesive layer and the fourth adhesive layer of the display apparatus is greater than a thickness of the second panel.

In an embodiment of the disclosure, the display apparatus further includes a telescopic mechanism disposed on one side of the second stretchable film facing away from the first panel. The first panel, the first adhesive layer, the second adhesive layer, the first stretchable film and the second stretchable film form a stretchable panel along a stacking direction. The telescopic mechanism is adapted to drive the stretchable panel to deform along the stacking direction.

In an embodiment of the disclosure, a ratio of the Young's modulus of the first panel of the display apparatus to the Young's modulus of the first adhesive layer is less than or equal to 10⁵.

A central control platform of the disclosure includes a stretchable panel and at lea one telescopic mechanism. The stretchable panel includes a first panel, a first stretchable film and a first adhesive layer. The first stretchable film is disposed on one side of the first panel. The first adhesive layer connects the first panel and the first stretchable film. A ratio of the Young's modulus of the first panel to the Young's modulus of the first adhesive layer is greater than or equal to 1000, and less than or equal to 10⁵. The at least one telescopic mechanism is disposed on one side of the first panel facing away from the first stretchable film and is adapted to drive the stretchable panel to deform.

In an embodiment of the disclosure, the stretchable panel of the central control platform has an operating surface and a back surface opposite to each other. The at least one telescopic mechanism abuts against the back surface of the stretchable panel and is adapted to drive the stretchable panel to deform along a direction intersecting the operating surface.

In an embodiment of the disclosure, the at least one telescopic mechanism of the central control platform includes a plurality of telescopic mechanisms. The plurality of telescopic mechanisms are arranged at intervals along a first direction and a second direction that intersect each other. The first direction and the second direction are perpendicular to a normal direction of the operating surface.

In an embodiment of the disclosure, an orthographic projection of the plurality of telescopic mechanisms of the central control platform on the operating surface are arranged in a honeycomb pattern.

In an embodiment of the disclosure, each of the plurality of telescopic mechanisms of the central control platform is adapted to drive a portion of the stretchable panel to deform inward toward one side of the back surface or outward toward one side of the operating surface.

In an embodiment of the disclosure, the Young's modulus of the first panel of the central control platform is less than 100 MPa.

In an embodiment of the disclosure, the central control platform further includes second adhesive layer and a second stretchable film. The second adhesive layer is disposed on one side of the first panel facing away from the first stretchable film and connects the first panel. The second stretchable film is disposed on one side of the second adhesive layer facing away from the first panel and connects the second adhesive layer. A ratio of the Young's modulus of the first panel to the Young's modulus of the second adhesive layer is greater than or equal to 1000. The Young's modulus of each of the first stretchable film and the second stretchable film is less than the Young's modulus of the first panel.

In an embodiment of the disclosure, a thickness of each of the first adhesive layer and the second adhesive layer of the central control platform is greater than a thickness of the first panel.

In an embodiment of the disclosure, the central control platform further includes second panel and a third adhesive layer. The second panel is disposed on one side of the second stretchable film facing away from the first panel. The third adhesive layer connects the second panel and the second stretchable film. A ratio of the Young's modulus of the second panel to the Young's modulus of the third adhesive layer is greater than or equal to 1000. The Young's modulus of the second panel is less than 100 MPa.

In an embodiment of the disclosure, the central control platform further includes fourth adhesive layer and a third stretchable film. The fourth adhesive layer is disposed on one side of the second panel facing away from the first panel and connects the second panel. A ratio of the Young's modulus of the second panel to the Young's modulus of the fourth adhesive layer is greater than or equal to 1000. The third stretchable film is disposed on one side of the fourth adhesive layer facing away from the second panel and connects the fourth adhesive layer. The Young's modulus of the third stretchable film is less than the Young's modulus of the second panel.

In an embodiment of the disclosure, a thickness of each of the third adhesive layer and the fourth adhesive layer of the central control platform is greater than a thickness of the second panel.

Based on the above, in a display apparatus according to an embodiment of the disclosure, a first stretchable film is attached to one side of a first panel via a first adhesive layer. Since a ratio of the Young's modulus of the first panel to that of the first adhesive layer is greater than or equal to 1000, the deformation capability of the display apparatus is significantly improved, and the stability of the deformation is also enhanced.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic diagram of a display apparatus according to an embodiment of the disclosure.

FIG. 2 is a schematic top view of the display apparatus of FIG. 1.

FIG. 3 is a schematic cross-sectional view of the display apparatus of FIG. 1.

FIG. 4 is a schematic cross-sectional view of a stretchable panel of FIG. 1.

FIG. 5 is a schematic cross-sectional view of a stretchable panel according to another embodiment of the disclosure.

FIG. 6A is a schematic cross-sectional view of a localized recess of the display apparatus of FIG. 1.

FIG. 6B is a schematic cross-sectional view of a localized protrusion of the display apparatus of FIG. 1.

### DESCRIPTION OF THE EMBODIMENTS

The exemplary embodiments of the present invention will now be described in detail with reference to the accompanying drawings. Wherever possible, identical reference numerals are used in the drawings and descriptions to denote the same or similar parts.

It should be understood that when components, such as layers, films, regions, or substrates, are referred to as being “on” or “connected to” another component, they may be directly on or connected to the other component, or intermediate components may also be present. Conversely, when a component is referred to as being “directly on another component” or “directly connected to” another component, no intermediate components are present. As used herein, “connected” may refer to physical and/or electrical connection. Furthermore, “electrical connection” or “coupling” may involve other components between the two elements.

The terms “about”, “approximately”, or “substantially” used herein include the stated value and the average value within an acceptable deviation range, as determined by those skilled in the art, considering the specific amount of measurement error related to the measurements being discussed (i.e., limitations of the measurement system). For example, “about” may represent within one or more standard deviations of the stated value, or within ±30%, ±20%, ±10%, or ±5%. Furthermore, “about”, “approximately” or “substantially” may be chosen to represent an acceptable deviation range or standard deviation based on optical properties, etching properties, or other characteristics, without requiring the same standard deviation to apply to all properties.

Unless otherwise defined, all terms used herein (including technical and scientific terms) have the meanings commonly understood by those skilled in the art to which this invention pertains. It will be further understood that terms defined in commonly used dictionaries should be interpreted to have meanings consistent with their usage in the relevant technology and context of this invention, and not in an idealized or overly formal sense, unless explicitly defined as such in this document.

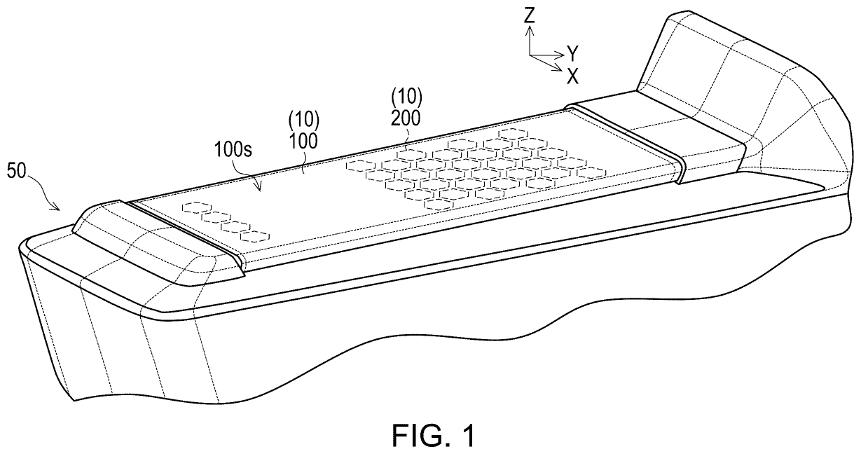

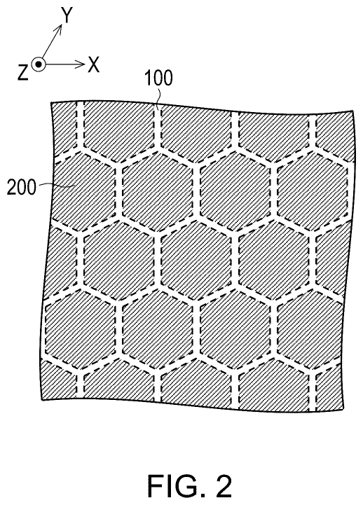

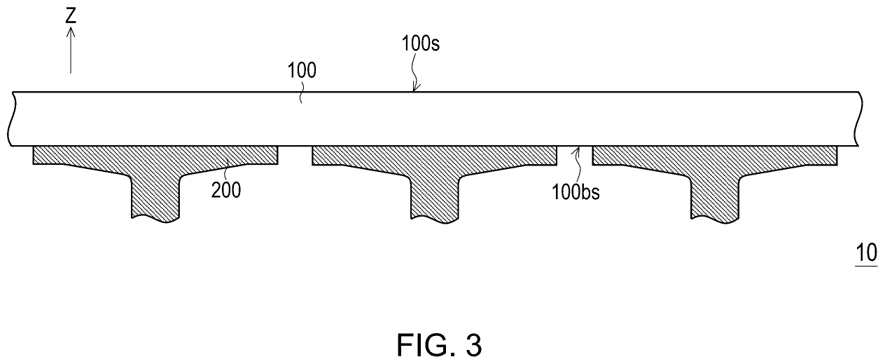

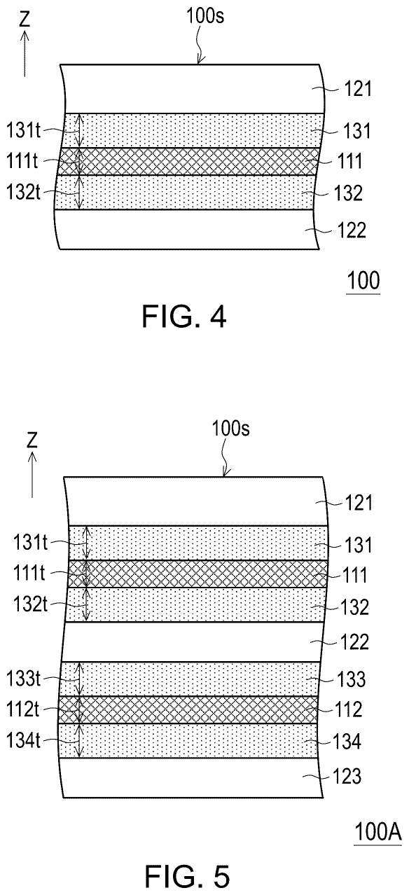

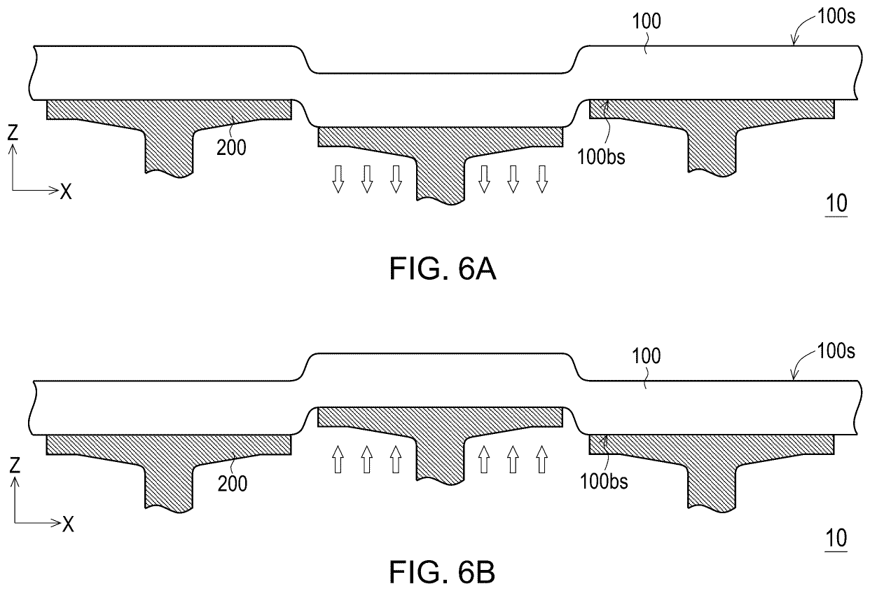

FIG. 1 is a schematic diagram of a display apparatus according to an embodiment of the disclosure. FIG. 2 is a schematic top view of the display apparatus of FIG. 1. FIG. 3 is a schematic cross-sectional view of the display apparatus of FIG. 1. FIG. 4 is a schematic cross-sectional view of a stretchable panel of FIG. 1. FIG. 5 is a schematic cross-sectional view of a stretchable panel according to another embodiment of the disclosure. FIG. 6A is a schematic cross-sectional view of a localized recess of the display apparatus of FIG. 1. FIG. 6B is a schematic cross-sectional view of a localized protrusion of the display apparatus of FIG. 1.

Referring to FIG. 1 to FIG. 3, a display apparatus 10 of the embodiment can be applied in the field of in-vehicle displays, such as a display/operating interface of a central control platform 50, but the disclosure is not limited thereto. In other embodiments, the display apparatus 10 may also be applied in other devices that require a human-machine interface.

In detail, the display apparatus 10 includes a stretchable panel 100 and a plurality of telescopic mechanisms 200. The stretchable panel 100 has an operating surface 100s, and the telescopic mechanisms 200 are arranged on one side of the stretchable panel 100 facing away from the operating surface 100s. For example, in the embodiment, the stretchable panel 100 may include a plurality of island structures (not shown) having a display function or a touch function and a bridging structure (not shown) connected between these island structures. The spacing between these island structures changes as the stretchable panel 100 operates in different deformation states. The stretchable panel 100 may be a display panel, a touch panel, or a combination thereof.

For example, in the embodiment, the plurality of telescopic mechanisms 200 may be arranged at intervals along a direction X and a direction Y, wherein the direction X and the direction Y intersect each other and are perpendicular to a direction Z. More specifically, these telescopic mechanisms 200 are arranged in a honeycomb pattern in a normal direction (e.g., direction Z) of the operating surface 100s of the stretchable panel 100. However, the disclosure is not limited thereto. In other embodiments, the arrangement of these telescopic mechanisms 200 may be adjusted according to the actual application of the display apparatus.

In the embodiment, each of the plurality of telescopic mechanisms 200 may abut against a back side 100bs of the stretchable panel 100 facing away from the operating surface 100s, and is adapted to drive the stretchable panel 100 to deform along a direction (e.g., direction Z) intersecting the operating surface 100s. More specifically, the telescopic mechanism 200 is used to drive a portion of the stretchable panel 100 to deform inward toward one side facing away from the operating surface 100s (as shown in FIG. 6A), or to drive a portion of the stretchable panel 100 to deform outward toward one side of the operating surface 100s (as shown in FIG. 6B). The aforementioned portion of the stretchable panel 100 is, for example, a portion where the stretchable panel 100 is connected to each telescopic mechanism 200.

Referring to FIG. 3 and FIG. 4, the stretchable panel 100 may include a first panel 111, a first stretchable film 121, a second stretchable film 122, a first adhesive layer 131, and a second adhesive layer 132. In the embodiment, the first stretchable film 121 and the second stretchable film 122 are respectively disposed on opposite sides of the first panel 111. The first adhesive layer 131 connects the first panel 111 and the first stretchable film 121. The second adhesive layer 132 is disposed on one side of the first panel 111 facing away from the first stretchable film 121, and connects the first panel 111 and the second stretchable film 122.

More specifically, the first stretchable film 121 is attached to one side surface of the first panel 111 via the first adhesive layer 131, and the second stretchable film 122 is attached to the other side surface of the first panel 111 via the second adhesive layer 132. In the embodiment, the surface of the first stretchable film 121 facing away from the first panel 111 can be defined as the operating surface 100s of the stretchable panel 100, but the disclosure is not limited thereto. In the embodiment, the telescopic mechanism 200 is adapted to drive the stretchable panel 100 to deform along a stacking direction (e.g., direction Z) of the first panel 111, the first stretchable film 121, the second stretchable film 122, the first adhesive layer 131, and the second adhesive layer 132.

In the stacking direction of the aforementioned multiple film layers, the first panel 111, the first adhesive layer 131 and the second adhesive layer 132 have a thickness 111t, a thickness 131t and a thickness 132t, respectively. In the embodiment, the thickness 131t of the first adhesive layer 131 and the thickness 132t of the second adhesive layer 132 may be greater than the thickness 111t of the first panel 111. For example, the thickness 111t of the first panel 111 may be 20 μm, and the thicknesses of each of the first adhesive layer 131 and the second adhesive layer 132 may be 50 μm. Since the first panel 111 is relatively thin, the first stretchable film 121 and the second stretchable film 122 attached to opposite sides of the first panel 111 can provide a protective effect for the first panel 111.

On the other hand, the first panel 111 may be provided with the aforementioned multiple island structures having display function or touch function and a bridging structure connected between these island structures. In the embodiment, the Young's modulus of the first panel 111 may be preferably less than 100 MPa. That is, the first panel 111 of the embodiment has stretchability.

It is particularly noted that the Young's modulus of each of the first stretchable film 121, the second stretchable film 122, the first adhesive layer 131 and the second adhesive layer 132 is less than the Young's modulus of the first panel 111. More specifically, a ratio of the Young's modulus of the first panel 111 to the Young's modulus of each of the first adhesive layer 131 and the second adhesive layer 132 is greater than or equal to 1000. For example, in the embodiment, the Young's modulus of the first panel 111 is 10 MPa, the Young's modulus of each of the first adhesive layer 131 and the second adhesive layer 132 is 0.01 MPa, the Young's modulus of the first stretchable film 121 is 3 MPa, and the Young's modulus of the second stretchable film 122 is 2.5 MPa, but the disclosure is not limited thereto.

Since the ratio of the Young's modulus of the first panel 111 to the adhesive layer is greater than or equal to 1000, when the stretchable panel 100 undergoes deformation under force, the resulting maximum strain is concentrated in the first adhesive layer 131 and the second adhesive layer 132, rather than in the first panel 111. Therefore, the deformation capability of the display apparatus 10 can be significantly improved, such as by increasing the indentation depth of the stretchable panel 100 during the deformation shown in FIG. 6A, or the protrusion height during the deformation shown in FIG. 6B.

Preferably, a ratio of the Young's modulus of the first panel 111 to the Young's modulus o f each of the first adhesive layer 131 and the second adhesive layer 132 is less than or equal to 10⁵. Accordingly, it can prevent the bonding yield of the stretchable film to the first panel 111 from being affected by the low Young's modulus of the adhesive layer.

Referring to FIG. 5, in another embodiment, a stretchable panel 100A may further include a second panel 112, a third stretchable film 123, a third adhesive layer 133, and a fourth adhesive layer 134. The second panel 112 is disposed on one side of the second stretchable film 122 facing away from the first panel 111. The third stretchable film 123 is disposed on one side of the second panel 112 facing away from the first panel 111. The third adhesive layer 133 connects the second panel 112 and the second stretchable film 122. The fourth adhesive layer 134 is disposed on one side of the second panel 112 facing away from the first panel 111 and connects the third stretchable film 123 and the second panel 112. More specifically, the second stretchable film 122 is attached to one side surface of the second panel 112 via the third adhesive layer 133, and the third stretchable film 123 is attached to the other side surface of the second panel 112 via the fourth adhesive layer 134.

In a stacking direction of the aforementioned multiple film layers, the second panel 112, the third adhesive layer 133 and the fourth adhesive layer 134 have a thickness 112t, a thickness 133t and a thickness 134t, respectively. In the embodiment, the thickness 133t of the third adhesive layer 133 and the thickness 134t of the fourth adhesive layer 134 may be greater than the thickness 112t of the second panel 112. For example, the thickness 112t of the second panel 112 may be 20 μm, and the thickness of each of the third adhesive layer 133 and the fourth adhesive layer 134 may be 50 μm. Since the second panel 112 is relatively thin, the second stretchable film 122 and the third stretchable film 123 attached to the opposite sides of the second panel 112 can provide a protective effect for the second panel 120.

In the embodiment, the first panel 111 may be provided with the aforementioned multiple island structures having touch functions and a bridging structure connecting these island structures, and the second panel 112 may be provided with the aforementioned multiple island structures having display functions and a bridging structure connecting these island structures. In the embodiment, the Young's modulus of each of the first panel 111 and the second panel 112 is preferably less than 100 MPa. That is, the first panel 111 and the second panel 112 of the embodiment both have stretchability.

It is particularly noted that the Young's modulus of each of the second stretchable film 122, the third stretchable film 123, the third adhesive layer 133 and the fourth adhesive layer 134 is less than the Young's modulus of the second panel 112. More specifically, a ratio of the Young's modulus of the second panel 112 to the Young's modulus of each of the third adhesive layer 133 and the fourth adhesive layer 134 is greater than or equal to 1000. For example, in the embodiment, the Young's modulus of each of the first panel 111 and the second panel 112 is 10 MPa, the Young's modulus of each of the first adhesive layer 131, the second adhesive layer 132, the third adhesive layer 133 and the fourth adhesive layer 134 is 0.01 MPa, the Young's modulus of the first stretchable film 121 is 3 MPa, and the Young's modulus of each of the second stretchable film 122 and the third stretchable film 123 is 2.5 MPa, but the disclosure is not limited thereto.

Since the ratio of the Young's modulus of the second panel 112 to the adhesive layer is greater than or equal to 1000, when the stretchable panel 100 undergoes deformation under force, the resulting maximum strain is concentrated in the third adhesive layer 133 and the fourth adhesive layer 134, rather than in the second panel 112. Therefore, the deformation capability of the display apparatus can be significantly improved, such as by increasing the indentation depth of the stretchable panel 100A during the deformation shown in FIG. 6A, or the protrusion height during the deformation shown in FIG. 6B.

Preferably, a ratio of the Young's modulus of the second panel 112 to the Young's modulus of each of the third adhesive layer 133 and the fourth adhesive layer 134 is less than or equal to 10⁵. Accordingly, it can prevent the bonding yield of the stretchable film to the second panel 112 from being affected by the low Young's modulus of the adhesive layer.

To sum up, in a display apparatus according to an embodiment of the disclosure, first stretchable film is attached to one side of a first panel via a first adhesive layer. Since a ratio of the Young's modulus of the first panel to that of the first adhesive layer is greater than or equal to 1000, the deformation capability of the display apparatus is significantly improved, and the stability of the deformation is also enhanced.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A display apparatus, comprising:
a first panel;
a first stretchable film, disposed on one side of the first panel; and
a first adhesive layer, connecting the first panel and the first stretchable film, wherein a ratio of the Young's modulus of the first panel to the Young's modulus of the first adhesive layer is greater than or equal to 1000.

2. The display apparatus according to claim 1, further comprising:
a second adhesive layer, disposed on one side of the first panel facing away from the first stretchable film and connecting the first panel, wherein a ratio of the Young's modulus of the first panel to the Young's modulus of the second adhesive layer is greater than or equal to 1000.

3. The display apparatus according to claim 2, wherein a thickness of each of the first adhesive layer and the second adhesive layer is greater than a thickness of the first panel.

4. The display apparatus according to claim 2, further comprising:
a second stretchable film, disposed on one side of the second adhesive layer facing away from the first panel and connecting the second adhesive layer, wherein the Young's modulus of each of the first stretchable film and the second stretchable film is less than the Young's modulus of the first panel.

5. The display apparatus according to claim 4, further comprising:
a second panel, disposed on one side of the second stretchable film facing away from the first panel; and
a third adhesive layer, connecting the second panel and the second stretchable film, wherein a ratio of the Young's modulus of the second panel to the Young's modulus of the third adhesive layer is greater than or equal to 1000.

6. The display apparatus according to claim 5, wherein the Young's modulus of each of the first panel and the second panel is less than 100 MPa.

7. The display apparatus according to claim 5, further comprising:
a fourth adhesive layer, disposed on one side of the second panel facing away from the first panel and connecting the second panel, wherein a ratio of the Young's modulus of the second panel to the Young's modulus of the fourth adhesive layer is greater than or equal to 1000; and
a third stretchable film, disposed on one side of the fourth adhesive layer facing away from the second panel and connecting the fourth adhesive layer, wherein the Young's modulus of the third stretchable film is less than the Young's modulus of the second panel.

8. The display apparatus according to claim 7, wherein a thickness of each of the third adhesive layer and the fourth adhesive layer is greater than a thickness of the second panel.

9. The display apparatus according to claim 4, further comprising:
a telescopic mechanism, disposed on one side of the second stretchable film facing away from the first panel, wherein the first panel, the first adhesive layer, the second adhesive layer, the first stretchable film and the second stretchable film form a stretchable panel along a stacking direction, and the telescopic mechanism is adapted to drive the stretchable panel to deform along the stacking direction.

10. The display apparatus according to claim 1, wherein a ratio of the Young's modulus of the first panel to the Young's modulus of the first adhesive layer is less than or equal to 10⁵.

11. A central control platform, comprising:
a stretchable panel, comprising:
a first panel;
a first stretchable film, disposed on one side of the first panel; and
a first adhesive layer, connecting the first panel and the first stretchable film, wherein a ratio of the Young's modulus of the first panel to the Young's modulus of the first adhesive layer is greater than or equal to 1000, and less than or equal to 10⁵; and
at least one telescopic mechanism, disposed on one side of the first panel facing away from the first stretchable film and adapted to drive the stretchable panel to deform.

12. The central control platform according to claim 11, wherein the stretchable panel has an operating surface and a back surface opposite to each other, the at least one telescopic mechanism abuts against the back surface of the stretchable panel and is adapted to drive the stretchable panel to deform along a direction intersecting the operating surface.

13. The central control platform according to claim 12, wherein the at least one telescopic mechanism includes a plurality of telescopic mechanisms, the plurality of telescopic mechanisms are arranged at intervals along a first direction and a second direction that intersect each other, and the first direction and the second direction are perpendicular to a normal direction of the operating surface.

14. The central control platform according to claim 13, wherein an orthographic projection of the plurality of telescopic mechanisms on the operating surface are arranged in a honeycomb pattern.

15. The central control platform according to claim 13, wherein each of the plurality of telescopic mechanisms is adapted to drive a portion of the stretchable panel to deform inward toward one side of the back surface or outward toward one side of the operating surface.

16. The central control platform according to claim 11, wherein the Young's modulus of the first panel is less than 100 MPa.

17. The central control platform according to claim 11, further comprising:
a second adhesive layer, disposed on one side of the first panel facing away from the first stretchable film and connecting the first panel; and
a second stretchable film, disposed on one side of the second adhesive layer facing away from the first panel and connecting the second adhesive layer, wherein a ratio of the Young's modulus of the first panel to the Young's modulus of the second adhesive layer is greater than or equal to 1000, and the Young's modulus of each of the first stretchable film and the second stretchable film is less than the Young's modulus of the first panel.

18. The central control platform according to claim 17, wherein a thickness of each of the first adhesive layer and the second adhesive layer is greater than a thickness of the first panel.

19. The central control platform according to claim 17, further comprising:
a second panel, disposed on one side of the second stretchable film facing away from the first panel; and
a third adhesive layer, connecting the second panel and the second stretchable film, wherein a ratio of the Young's modulus of the second panel to the Young's modulus of the third adhesive layer is greater than or equal to 1000, and the Young's modulus of the second panel is less than 100 MPa.

20. The central control platform according to claim 19, further comprising:
a fourth adhesive layer, disposed on one side of the second panel facing away from the first panel and connecting the second panel, wherein a ratio of the Young's modulus of the second panel to the Young's modulus of the fourth adhesive layer is greater than or equal to 1000; and
a third stretchable film, disposed on one side of the fourth adhesive layer facing away from the second panel and connecting the fourth adhesive layer, wherein the Young's modulus of the third stretchable film is less than the Young's modulus of the second panel.
